(19) United States
(12) Patent Application Publication
(10) Pub. No.: US 2026/0181778 A1
(43) Pub. Date: Jun. 25, 2026

(54) Flexible Circuit Board and Multi-Zone Dimming Functional Element

(71) Applicants: FEW Automotive Electric Co., Ltd., Shanghai (CN); FEW Flexible Circuit Board (Shenzhen) Co., Ltd., Shenzhen (CN)

(72) Inventors: Xiongbin Gu, Shenzhen (CN); Ying Leibnitz, Leipzig (DE); Thomas Krabs, Leipzig (DE); Andreas Knoll, Oelsnitz (DE)

(73) Assignees: FEW Automotive Electric Co., Ltd., Shanghai (CN); Few Flexible Circuit Board (Shenzhen) Co., Ltd., Shenzhen (CN)

(21) Appl. No.: 19/431,556

(22) Filed: Dec. 23, 2025

(30) Foreign Application Priority Data
Dec. 24, 2024 (CN) 2024231898829

(51) Int. Cl. H05K 1/11; G02F 1/133; H05K 1/181

(52) U.S. Cl. CPC H05K 1/118; G02F 1/13306; H05K 1/181; H05K 2201/10151; H05K 2201/10984

(57) ABSTRACT

The present application relates to the field of local-dimming, and in particular, relates to a flexible circuit board and a multi-zone dimming functional element. The flexible circuit board specifically includes a first independent circuit group and a second independent circuit group. The first independent circuit group includes multiple first independent circuits, each contacting a dimming area of the functional element and connecting the dimming area to a control unit. The second independent circuit group includes multiple second independent circuits and at least one temperature sensor for measuring the temperature of the functional element within a temperature measurement area. Integrating the first terminal, second terminal, and temperature sensor on the flexible circuit board reduces the number of connectors and solder joints, improving the system's integration and reliability.

### TECHNICAL FIELD

The present application relates to the field of local-dimming, and in particular, relates to a flexible circuit board and a multi-zone dimming functional element.

### BACKGROUND

At present, local dimming belongs to a new industry. In an existing generation process, a common circular copper wire is soldered to a dimming film through solder paste. A large quantity of copper wires are large in size, and occupy much space, which is inconducive to a miniaturization design of a device. A great amount of manual power is needed in connecting and assembling processes of circular copper wires, and therefore, the process is complex and is likely to have an error. In addition, when the circular copper wire is broken or is in poor contact, it is difficult to repair and replace the circular copper wire due to high maintenance costs.

### SUMMARY

Therefore, to overcome disadvantages in the prior art, the present application discloses a flexible circuit board that is in contact with a functional element (1) with an electrically controllable optical characteristic, including:

a first independent circuit group (21) including a plurality of first independent circuits, where each first independent circuit is in contact with a dimming zone (11) of the functional element (1), and the dimming zone (11) is connected to a control unit (3);

a second independent circuit group (22) including a plurality of second independent circuits, where the second independent circuit group (22) includes at least one temperature sensor (25), and the temperature sensor (25) is configured to measure the temperature of the functional element (1) in a temperature measurement zone (12), where each positive electrode of the functional element (1) is connected to the control unit (3) through a first terminal (23) of the first independent circuit group (21), and a common negative electrode of the functional element (1) is connected to the control unit (3) through a second terminal (24) of the first independent circuit group (21).

Specifically, the flexible circuit board is in contact with the functional element (1) with the electrically controllable optical characteristic, and the functional element (1) is a polymer dispersed liquid crystal functional element, a polymer network liquid crystal functional element or a suspended particle functional element.

Specifically, the flexible circuit board is in contact with the functional element (1) with the electrically controllable optical characteristic, and the functional element (1) is a middle layer in multi-layer glass made of glass or optical transparent plastic.

Specifically, the flexible circuit board is in contact with the functional element (1) with the electrically controllable optical characteristic, and the functional element (1) is a middle layer in multi-layer glass for a vehicle or architectural glass.

Specifically, there are 2 to 49 positive electrodes in the functional element (1).

Specifically, the length of the flexible circuit board (2) is 20 mm to 4000 mm.

Specifically, the height of the temperature sensor (25) is less than 0.7 mm.

Specifically, a protective layer (26) is coated around the temperature sensor (25) and is configured to protect the temperature sensor (25) from mechanical effect.

Specifically, the protective layer (26) is an adhesive layer, and is configured to fasten the temperature sensor (25) in the temperature measurement zone (12).

Specifically, a connection layer made of solder paste or an anisotropic conductive adhesive is disposed between the positive electrode of the functional element (1) and the first terminal (23); and a connection layer made of solder paste or an anisotropic conductive adhesive is disposed between the negative electrode of the functional element (1) and the second terminal (24).

Specifically, the temperature sensor (25) is mounted on an independent flexible circuit board (27), the independent flexible circuit board (27) is connected to the flexible circuit board (2) through a connection layer, and the connection layer is made of solder paste or an anisotropic conductive adhesive.

Specifically, the flexible circuit board (2) includes a plurality of short flexible circuit boards connected in series, and the plurality of short flexible circuit boards are connected through a connection layer made of solder paste or an anisotropic conductive adhesive.

Compared with the prior art, the present application has the advantages that: High-density wiring and an ultralong wiring harness function are implemented through the flexible circuit board, and high-precision connection of a complex line is improved. In addition, more functional modules are integrated on the flexible circuit board, and the first terminal, the second terminal, and the temperature sensor are integrated on the flexible circuit board, so that real-time dimming control and temperature monitoring are implemented, the quantity of connectors and soldering spots is reduced, and integration and reliability of the system are improved. Moreover, an ultra-small thickness is still kept after the first terminal, the second terminal, and the temperature sensor are integrated on the flexible circuit board.

### BRIEF DESCRIPTION OF THE DRAWINGS

To describe the technical solutions of the embodiments of the present application more clearly, the following briefly introduces the accompanying drawings required for describing embodiments. Apparently, the accompanying drawings in the following description show only some embodiments of the present application, and a person of ordinary skill in the art may still derive other drawings from these accompanying drawings without creative efforts.

FIG. 1 is a schematic diagram of a structure in which a control unit controls multi-zone dimming of a functional element through a flexible circuit board according to an embodiment of the present application.

FIG. 2 is a schematic diagram of mounting a temperature sensor in an independent flexible circuit board according to an embodiment of the present application.

### DETAILED DESCRIPTION OF THE EMBODIMENTS

The following describes in detail embodiments of the present application with reference to the accompanying drawings.

The following describes implementations of the present application with specific embodiments, and a person skilled in the art may easily understand other advantages and effects of the present application with reference to content disclosed in the specification. Apparently, the described embodiments are merely some rather than all of embodiments of the present application. The present application may also be implemented or applied through different specific implementation methods, and various details in the specification may be modified or changed based on different perspectives and applications without departing from the spirit of the present application. It should be noted that, without conflict, the following embodiments and features in the embodiments may be combined with each other. Based on the embodiments of the present application, all other embodiments obtained by a person of ordinary skill in the art without creative efforts fall within the protection scope of the present application.

It should be noted that the following describes various aspects of the embodiments within the scope of the present application. It should be apparent that the aspects described in the specification may be embodied in a wide variety of forms, and any specific structure and/or function described in the specification is for an illustrative purpose only. Based on the present application, a person skilled in the art should understand that one aspect described in the specification may be implemented independently of any other aspect, and two or more of these aspects may be combined in various ways. For example, any number and aspect described in the specification may be used to implement the device and/or method. In addition, other structures and/or functional implementations other than those described in the specification may be used to implement the device and/or method.

It should be noted that the illustrations provided in the following embodiments only illustrate the basic concept of the present application in a schematic manner. The illustrations only show the components related to the present application and are not drawn according to an actual quantity, shapes, and sizes of the components during implementation. The shape, quantity, and proportion of each component during actual implementation may be arbitrarily changed, and layout of the components may also be more complex.

Furthermore, the following description provides specific details to facilitate a thorough understanding of the embodiments. However, a person skilled in the art may understand that it is possible to implement the aspects without these specific details.

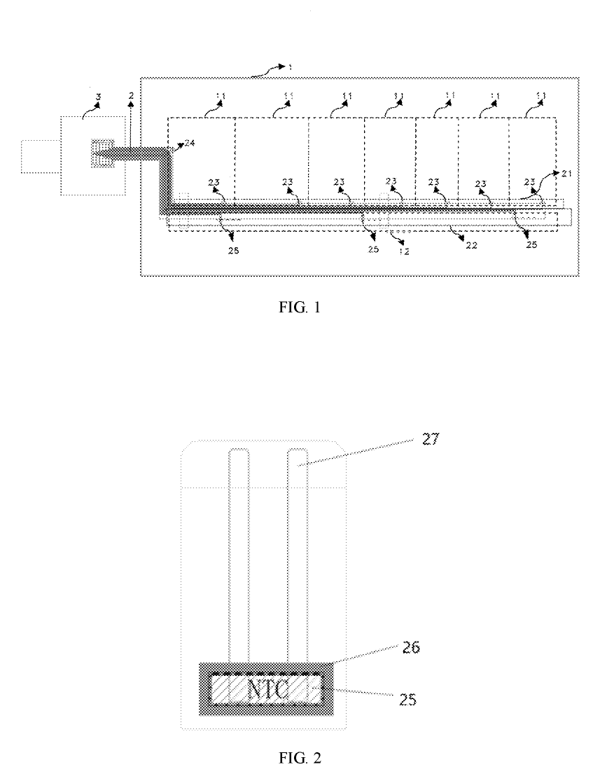

As shown in FIG. 1, an embodiment of the present application provides a multi-zone dimming functional element with an electrically controllable optical characteristic, including a functional element 1, a flexible circuit board 2, and a control unit 3.

A plurality of dimming zones 11 and a temperature measurement zone 12 are disposed in the functional element 1. Positive electrodes are separately disposed in the plurality of dimming zones 11, and a common negative electrode is disposed in the plurality of dimming zones. A signal given by the control unit 3 is received by the positive electrodes that are separately disposed in the plurality of the dimming zones 11, to control the state of a dimming film.

The flexible circuit board 2 is in contact with the functional element 1 with the electrically controllable optical characteristic, and the flexible circuit board 2 includes a first independent circuit group 21, and a second independent circuit group 22.

The first independent circuit group 21 includes a plurality of first independent circuits, where each first independent circuit is in contact with a dimming zone 11 of the functional element 1, and the first independent circuit group is configured to connect the control unit 3 to the plurality of dimming zones 11 in the functional element 1. The first independent circuit includes a plurality of first terminals 23 and a second terminal 24. The first terminal 23 is configured to connect the control unit 3 to each positive electrode of the functional element 1. The second terminal 24 is configured to connect the control unit 3 to a common negative electrode of the functional element 1.

The second independent circuit group 22 includes a plurality of second independent circuits. The second independent circuit group is configured to connect the control unit 3 to the temperature measurement zone 12 in the functional element 1. The second independent circuit includes at least one temperature sensor 25, and the temperature sensor 25 is configured to measure the temperature of the functional element 1 in the temperature measurement zone 12.

The flexible circuit board in this embodiment implements high-density wiring and an ultralong wiring harness function and improves high-precision connection of a complex circuit. In addition, more functional modules are integrated on the flexible circuit board, and the first terminal, the second terminal, and the temperature sensor are integrated on the flexible circuit board, so that real-time dimming control and temperature monitoring are implemented, the quantity of connectors and soldering spots is reduced, and integration and reliability of a system are improved. Moreover, an ultra-small thickness is still kept after the first terminal, the second terminal, and the temperature sensor are integrated on the flexible circuit board.

In an embodiment, the functional element 1 is a polymer disposed liquid crystal (PDLC) functional element, a polymer network liquid crystal (PNLC) functional element or a suspended particle (SPD) functional element. The PDLC is that liquid crystals are disposed in an organic solid polymer matrix in forms of micro-level droplets. Because optical axes of droplets formed by liquid crystal molecules are freely orientated, a refractive index of the droplet is not matched with a refractive index of the matrix. When light passes through the matrix, the light is strongly diffused by the droplets to be in a non-transparent milky-white state or a semi-transparent state. Directions of optical axes of the liquid crystal droplets can be adjusted by applying electric fields. When the retractive indexes are matched, a transparent state is shown. The liquid crystal droplets are returned to the original light-scattering state after the electric fields are removed. PNLC is a polymer network liquid crystal mode. Compared with those in PDLC, liquid crystals in PNLC are not spherical (or ellipsoidal) droplets, and are distributed in a polymer three-dimensional network, to form a continuous channel network. The suspended particle (SPD) functional element is a novel electrically controllable color-changing dimming glass product that is manufactured by combining a sensitometric characteristic of SPD with glass. The SPD functional element can replace a curtain for use, so that light transmission effect is freely adjusted, and proper indoor light is selected. When an SPD film is applied with an alternating-current voltage, particles are orientated and arranged under action of electric fields, so that the light passes through.

In an embodiment, the functional element 1 is a middle layer in multi-layer glass made of glass or optical transparent plastic. The flexible circuit board 2 is disposed on the middle layer of glass or multi-layer glass.

In an embodiment, the functional element 1 is a middle layer of multi-layer glass for a vehicle or architectural glass. The flexible circuit board 2 is disposed at the middle layer of the multi-layer glass.

In an embodiment, there are 2 to 49 positive electrodes in the functional element 1. That is, there are 2 to 49 first terminals 23 in the flexible circuit board 2. A quantity of first terminals 23 of the first independent circuit group 21 is consistent with that of positive electrodes in the functional element 1. The first terminals 23 of the first independent circuit group 21 are in one-to-one correspondence to the positive electrodes in the functional element 1. Each positive electrode of the functional element 1 is connected to the control unit 3 through the first terminal 23 of the first independent circuit group 21. The control unit 3 implements multi-zone dimming control.

In an embodiment, the length of the flexible circuit board 2 is 20 mm to 4000 mm. The length of the flexible circuit 2 is 20 mm to 4000 mm, so that the flexible circuit board can cross the long functional element 1, to implement a multi-dimension requirement of the functional element 1.

In an embodiment, the height of the temperature sensor 25 is less than 0.7 mm. The temperature sensor 25 may be set to be thin, so as to be completely pressed into the functional element 1.

In an embodiment, as shown in FIG. 2, a protective layer (26) is disposed around the temperature sensor 25, and is configured to protect the temperature sensor 25 from mechanical effect.

In an embodiment, the protective layer (26) disposed around the temperature sensor 25 is an adhesive layer. The adhesive layer is configured to fasten the position of the temperature sensor 25 in the functional element 1. The adhesive layer is disposed around, not disposed on a top of the temperature sensor 25, so that the temperature sensor 25 is in direct contact with the temperature measurement zone 12 of the functional element 1. This prevents the adhesive layer from affecting temperature measurement sensitivity of the temperature sensor 25.

In an embodiment, a connection layer made of solder paste or an anisotropic conductive adhesive is disposed between the positive electrode of the functional element 1 and the first terminal 23; and a connection layer made of solder paste or an anisotropic conductive adhesive is disposed between the negative electrode of the functional element 1 and the second terminal 24. Through solder paste soldering or an anisotropic conductive adhesive pressing process, the positive electrode is tightly fastened to the first terminal 23, and the negative electrode is tightly fastened to the second terminal 24.

In an embodiment, as shown in FIG. 2, the temperature sensor 25 is mounted on an independent flexible circuit board (27). The independent flexible circuit board (27) is connected to the flexible circuit board 2 through the connection layer made of solder paste or an anisotropic conductive adhesive.

In an embodiment, the long flexible circuit board may include a plurality of short flexible circuit boards that are sequentially connected in series. The flexible circuit board 2 includes a plurality of short flexible circuit boards, and the plurality of short circuit boards are connected through the connection layer made of solder paste or an anisotropic conductive adhesive.

### Embodiment 1

The functional element 1 is a middle layer of multi-layer glass for a vehicle or architectural glass. A plurality of dimming zones 11 and a temperature measurement zone 12 are disposed in the middle layer of the multi-layer glass. Positive electrodes of the functional element 1 are disposed on a same side edge of the dimming zones 11 side by side, and a common negative electrode of the functional element 1 is disposed on a side of the dimming zone 11. The dimming zone 11 receives a signal given by a control unit 3 through the flexible circuit board 2, to control the state of the dimming zone 11.

The flexible circuit board 2 is disposed at the middle layer of the multi-layer glass, and the flexible circuit board 2 includes a first independent circuit group 21, and a second independent circuit group 22.

The first independent circuit group 21 includes a plurality of first independent circuits that are independent of each other and are disposed side by side. The first independent circuits include a plurality of positive independent circuits and one negative independent circuit. The first independent circuit group is configured to connect the control unit 3 to the plurality of dimming zones 11 in the functional element 1. The negative independent circuit is disposed at a side of a closet dimming zone 11 in the first independent circuit group 21. From an electrical control side to a non-electrical control side, the length of the first independent circuit gradually increases, and the first independent circuit between the first independent circuit group and the second independent circuit group is longest. That is, from the dimming zone 11 to the temperature measurement zone 12, the length of the first independent circuit gradually increases. Tail ends of the plurality of positive independent circuits are guided to a side edge that is of the second independent circuit group and that is away from the first independent circuit group. In other words, a straight-line positive independent circuit tail end connection point is formed at an edge of the dimming zone 12 of the flexible circuit board 2.

The second independent circuit group 22 and the first independent circuit group 21 are disposed on the same plane, and independent circuits in the two are disposed side by side. The second independent circuit group 22 includes a plurality of second independent circuits. The second independent circuit group is configured to connect the control unit 3 to the temperature measurement zone 12 in the functional element 1. From an electrical control side to a non-electrical control side, the length of the first independent circuit gradually increases, and the second independent circuit between the first independent circuit group and the second independent circuit group is the longest. That is, from the temperature measurement zone 12 to the dimming zone 11, the length of the second independent circuit gradually increases. Tail ends of the second independent circuits are guided to a side edge that is of the second independent circuit group and that is away from the first independent circuit group. That is, a straight-line second independent circuit tail end connection point is formed at an edge of the temperature measurement zone 12 of the flexible circuit board 2.

The first terminal 23 is disposed between the first independent circuit and the dimming zone 11 for connecting the first independent circuit to the dimming zone 11. The first terminal 23 is integrated into the first independent circuit group 21. The plurality of first terminals 23 and the plurality of dimming zones 11 are disposed in one-to-one correspondence for separately performing dimming control.

The second terminal 24 is disposed at a tail end of the negative independent circuit of the first independent circuit group 21 for connecting the first independent circuit to the common negative electrode of the dimming zone 11. The second terminal 24 separately communicates with the plurality of first terminals 23. The control unit 3, the positive independent circuit, the first terminal 23, the second terminal 24, and the negative independent circuit form a closed conduction loop. The control unit 3 may control the dimming zone 11.

At least one temperature sensor 25 is disposed between the second independent circuit group 22 and the temperature measurement zone 12, that is, disposed at the tail end of the independent circuit in the second independent circuit group 22 for connecting the second independent circuit to the temperature measurement zone. For temperature monitoring in the temperature measurement zone 12, there may be 3 to 9 temperature sensors 25 that are uniformly disposed in the temperature measurement zone 12 side by side, so that temperature monitoring sensitivity and uniformity are improved.

The foregoing descriptions are merely specific implementations of the present application but are not intended to limit the protection scope of the present application. Any variation or replacement easily made by a person skilled in the art within the technical scope disclosed in the present application shall fall within the protection scope of this application.

What is claimed is:

1. A flexible circuit board (2) that is in contact with a function element (1) with an electrically controllable optical characteristic comprising:
a first independent circuit group (21) comprising a plurality of first independent circuits, wherein each first independent circuit is in contact with a dimming zone (11) of the functional element (1), and the dimming zone (11) is connected to a control unit (3);
a second independent circuit group (22) comprising a plurality of second independent circuits, wherein the second independent circuit group (22) comprises at least one temperature sensor (25), and the temperature sensor (25) is configured to measure a temperature of the functional element (1) in a temperature measurement zone (12), wherein
each positive electrode of the functional element (1) is connected to the control unit (3) through a first terminal (23) of the first independent circuit group (21), and a common negative electrode of the functional element (1) is connected to the control unit (3) through a second terminal (24) of the first independent circuit group (21).

2. A flexible circuit board (2) according to claim 1, wherein the flexible circuit board is in contact with the functional element (1) with the electrically controllable optical characteristic, and the functional element (1) is a polymer dispersed liquid crystal functional element, a polymer network liquid crystal functional element or a suspended particle functional element.

3. A flexible circuit board (2) according to claim 1, wherein the flexible circuit board is in contact with the functional element (1) with the electrically controllable optical characteristic, and the functional element (1) is a middle layer in multi-layer glass made of glass or optically transparent plastic.

4. A flexible circuit board (2) according to claim 1, wherein the flexible circuit board is in contact with the functional element (1) with the electrically controllable optical characteristic, and the functional element (1) is a middle layer in multi-layer glass for a vehicle or architectural glass.

5. A flexible circuit board (2) according to claim 1, wherein there are 2 to 49 positive electrodes in the functional element (1).

6. A flexible circuit board (2) according to claim 1, wherein the length of the flexible circuit board (2) is 20 mm to 4000 mm.

7. A flexible circuit board (2) according to claim 1, wherein the height of the temperature sensor (25) is less than 0.7 mm.

8. A flexible circuit board (2) according to claim 1, wherein a protective layer (26) is coated around the temperature sensor (25) and is configured to protect the temperature sensor (25) from mechanical effect.

9. A flexible circuit board (2) according to claim 8, wherein the protective layer (26) is an adhesive layer, and is configured to fasten the temperature sensor (25) in the temperature measurement zone (12).

10. A flexible circuit board (2) according to claim 1, wherein a connection layer made of solder paste or an anisotropic conductive adhesive is disposed between the positive electrode of the functional element (1) and the first terminal (23); and a connection layer made of solder paste or an anisotropic conductive adhesive is disposed between the negative electrode of the functional element (1) and the second terminal (24).

11. A flexible circuit board (2) according to claim 1, wherein the temperature sensor (25) is mounted on an independent flexible circuit board (27), the independent flexible circuit board (27) is connected to the flexible circuit board (2) through a connection layer, and the connection layer is made of solder paste or an anisotropic conductive adhesive.

12. A flexible circuit board (2) according to claim 1, wherein the flexible circuit board (2) comprises a plurality of short flexible circuit boards connected in series, and the plurality of short flexible circuit boards are connected through a connection layer made of solder paste or an anisotropic conductive adhesive.
